(19) United States
(12) Patent Application Publication
(10) Pub. No.: US 2009/0202721 A1
(43) Pub. Date: Aug. 13, 2009

(54) Method for Thin Film Formation

(76) Inventors: Hiroshi Nogami, Kanagawa (JP); Katsuhisa Yuda, Tokyo (JP); Hiroshi Tanabe, Tokyo (JP)

Correspondence Address: WENDEROTH, LIND & PONACK, L.L.P., 1030 15th Street, N.W.,, Suite 400 East, Washington, DC, 20005-1503, US

(21) Appl. No.: 11/886,317

(22) PCT Filed: Mar. 14, 2006
(86) PCT No.: PCT/JP2006/305013

§ 371 Date: Jun. 23, 2008

(30) Foreign Application Priority Data
Mar. 15, 2005 (JP) 2005-073217

(51) Int. Cl. C23C 16/00; C23C 16/54

(52) U.S. Cl. 427/255.23; 118/723 E

(57) ABSTRACT

A method for thin film formation that can form, at a low temperature, a good thin film having a good interfacial property between a silicon substrate and a silicon oxide film and having a low interfacial trap density is provided.

The method for thin film formation comprises generating plasma within a vacuum vessel to generate an active species (radical) and forming a silicon oxide film on a silicon substrate using this active species and a material gas, wherein, in addition to the material gas, a nitrogen atom-containing gas is introduced into the vacuum vessel in its film forming space where the active species (radical) and the material gas come into contact with each other for the first time and are reacted with each other to form a silicon film on the silicon substrate, and wherein the flow rate of the nitrogen atom-containing gas during the formation of the silicon oxide film on the silicon substrate is regulated so as to be the maximum value at least at the time of the start of formation of the silicon film on the silicon substrate.

### BACKGROUND

1. Technical Field

The present invention relates to a thin film formation method in which a silicon oxide film may be formed on a silicon substrate, and more particularly to the thin film formation method that may be performed by utilizing the chemical reaction using an active species (radical).

2. Background

The substrate processing apparatus and method are known and used in various applications, in which substrates that are placed within the vacuum vessel of the apparatus may be processed by generating an active species (radical) by forming plasma within the vacuum vessel. For example, the substrates are processed so that the thin films can be formed on the substrates, and the surface processing is performed in order to improve the film quality of the thin films thus formed on the substrates.

When the liquid crystal displays are manufactured using the polysilicon-type TFT at a low temperature, for example, the conventional substrate processing apparatus and method use the plasma CVD in forming the appropriate silicon oxide films serving as the gate insulating films at the low temperature.

Among others, the inventors of the current application proposed the CVD system in their prior Japanese unexamined patent application No. 2000-345349, in which a substrate that is placed within the vacuum vessel of the apparatus may be processed by generating radicals by forming plasmas within the vacuum vessel (in this specification, the CVD system proposed in the above prior application will be referred to as the “Radical Shower CVD system”, or in short the “RS-CVD system”, in order to distinguish the RS-CVD system from the ordinary plasma CVD system.

In the application No. 2000-345349, it is described that the RS-CDV system may be used to generate radicals by forming plasmas within the vacuum vessel, wherein the thin film formation processing may be performed on the substrates by using those radicals together with the thin film forming gases.

Specifically, the RS-CVD system disclosed in No. 2000-345349, as well as its operation, will be described below.

The vacuum vessel is internally separated into two compartments by a conductive partition plate, one of the compartments being plasma generating space in which a high frequency electrode is placed, and the other being a film forming space in which a substrate holding mechanism on which a substrate is firmly held is disposed. The conductive partition plate has a plurality of penetration holes through which the plasma generating space and film forming space may communicate with each other, and a first inner space separated from the plasma generating space and communicating with the film forming space through a plurality of material gas diffusion holes. Gas may be introduced into the plasma generating space so that the desired radicals can be generated from the discharged plasma. Then, the desired radicals thus generated in the plasma generating space may be introduced into the film forming space through the plurality of penetrating holes on the conductive partition plate. In the meantime, the material gas that has been supplied into the first inner space from any suitable external source may be introduced into the film forming space through the plurality of material gas diffusion holes. In this way, the thin film may be formed on the substrate by causing the radicals and material gas to react with each other.

It may be appreciated from the description of the RS-CVD system and its operation disclosed in No. 2000-345349 that the radicals generated in the plasma generating space may only be introduced into the film forming space through the plurality of penetrating holes, and the material gas supplied into the first inner space inside the conductive partition plate from the external source may be introduced into the film forming space through the plurality of material gas diffusion holes. Thus, the material gas can be introduced from outside the vacuum vessel without directly making contact with the film forming space, that is, the plasma and radicals.

### SUMMARY OF THE INVENTION

In the manufacture of the liquid crystal displays using the polysilicon-type TFT as described above, it is required that the insulating film obtained at the low temperature have a good interfacial property in order to permit the insulating film to be applied as the gate oxide film. The dangling bonds on the Si surface may remain even after the interface between the silicon oxide film and silicon has been formed, and it is therefore difficult to obtain the good interfacial property with regard to the interfacial trap density associated with the silicon oxide film and silicon.

In some CVD methods, the process may be terminated by the hydrogen atoms, but the bonds may be broken while the subsequent process occurs at about 40° C. As the long-term reliability cannot be provided, the sufficient interfacial property cannot be obtained. As such, those methods are not suited to the production of the gate oxide films.

Accordingly, an object of the present invention is to provide a thin film forming method that allows for the manufacture of the silicon oxide films having the good interfacial property at the low temperature.

The inventors of the current application have discovered that the above-described problems can be solved by allowing the active species (radicals) and material gas to make contact with each other for the first time within the vacuum vessel of the RS-CVD system, thereby causing them to react with each other so that a silicon oxide film can be formed on a silicon substrate in the film forming space, introducing a nitrogen atom-contained gas as any suitable gas that is other than the material gas into the film forming space, and controlling the flow rate of the nitrogen atom-contained gas during the formation of the silicon oxide film on the silicon substrate so that it can be at least the maximum flow rate at the time of the start of the formation of the silicon oxide on the silicon substrate. The present invention is based upon the above discovery.

The thin film formation apparatus that may be used in conjunction with the thin film formation method to be described below includes a vacuum vessel that is internally separated into two compartments by means of a conductive partition plate, one of the compartments serving as a plasma generating space in which a high frequency electrode is disposed and the other serving as a film forming space in which a substrate holding mechanism is disposed, wherein the conductive partition plate has a plurality of penetrating holes through which the plasma generating space and film forming space communicate with each other, a first inner space separated from the plasma generating space and communicating with the film forming space through a plurality of material gas diffusion holes, and a second inner space separated from the first inner space and communicating with the plasma generating space through a plurality of gas diffusion holes, and wherein a gas may be introduced into the plasma generating space in which a desired active species (radicals) can be generated by the discharged plasma.

The thin film formation method that may be used in conjunction with the thin film forming apparatus having the construction described above comprises generating the desired active species (radicals) within the plasma generating space, introducing the generated active species into the film forming space through the plurality of penetrating holes on the conductive partition plate, introducing the material gas that has been supplied into the first inner space from any suitable external source into the film forming space through the plurality of material gas diffusion holes, introducing any suitable gas other than the material gas that is to be supplied into the second inner space from the external source into the film forming space through the plurality of gas diffusion holes, and causing the active species introduced into the film forming space to react with the material gas, thereby forming a silicon oxide film on the silicon substrate, wherein any gas as the suitable gas other than the material gas introduced into the second inner space may be a nitrogen atom-contained gas, and the flow rate of the nitrogen atom-contained gas during the formation of the silicon oxide film on the silicon substrate can be adjusted to at least the maximum flow rate at the start of the formation of the silicon oxide film on the silicon substrate.

In accordance with the present invention, the nitrogen atom-contained gas as any suitable gas other than the material gas may be introduced into the film forming space by way of the second inner space, and the flow rate of the nitrogen atom-contained gas that is being introduced into the film forming space by way of the second inner space may be adjusted to at least the maximum flow rate at the start of the formation of the silicon oxide film on the silicon substrate. Thus, the thin film may be formed in the neighborhood of the interface in the state in which the nitrogen atom-contained gas is mixed into the atmosphere within the film forming space, and the thin film thus formed can have an improved interfacial property.

Specifically, as the flow rate of the nitrogen atom-contained gas to be introduced into the film forming space can be adjusted to at least the maximum value at least at the start of formation of the silicon oxide film on the silicon substrate, the nitrogen atom contained in the silicon oxide film can have the highest density in the neighborhood of the interface between the silicon oxide film serving as the gate electrode and silicon. Thus, the dangling bonds on the Si surface can be reduced. As a result, the interfacial property can be improved.

The nitrogen atom-contained gases may preferably be any one or more of dinitrogen monoxide (N₂O), nitrogen monoxide (NO) and nitrogen dioxide (NO₂).

The flow rate of the nitrogen atom-contained gas being introduced into the second inner space may be adjusted to at least the maximum value, at least, at the start of formation of the silicon oxide film on the silicon substrate as described above. This maximum flow rate thus obtained may subsequently be adjusted in several ways. For example, the maximum flow rate may be maintained during a predetermined period from the time of starting the formation of the silicon oxide film on the silicon substrate until the time of ending the same, as shown in FIG. 2(a), or the maximum flow rate may be decreased continually with the elapse of the time, starting at the time of formation of the silicon oxide film on the silicon substrate, as shown in FIG. 2(b), or the maximum flow rate may be decreased gradually with the elapse of the time, starting at the time of formation of the silicon oxide film on the silicon substrate, as shown in FIG. 2(c).

In any of the thin film formation methods of the present invention described above, the nitrogen atom-contained gas as the suitable gas other than the material gas being introduced into the second inner space may be combined with the oxygen atom-contained gas as the suitable gas that is different from or other than the nitrogen atom-contained gas. In other words, the combination of the nitrogen atom-contained gas and oxygen atom-contained gas as the suitable gas that is different from or other than the nitrogen atom-contained gas may be introduced into the film forming space through the second inner space.

In this way, the oxygen can be supplemented actively during the formation of the silicon oxide film, and the silicon oxide film having the higher quality can thus be obtained.

In the case where the oxygen atom-contained gas that is different from the nitrogen atom-contained gas is also introduced into the film forming space through the second inner space, the flow rate of the nitrogen atom-contained gas being introduced into the second inner space can be adjusted to the value of 0 at the predetermined time between the start of formation of the silicon oxide film on the silicon substrate and the end of the same, and even after the flow rate of the nitrogen atom-contained gas being introduced into the second inner space has reached to the value of 0, the oxygen atom-contained gas as the suitable gas that is different from or other than the nitrogen atom-contained gas can continue to be introduced into the second inner space. This provides an advantage in that the oxygen can be supplemented actively during the formation of the silicon oxide film, and that the silicon oxide film having the higher quality can be formed.

It is noted that an example of the oxygen atom-contained gas as the suitable gas that is different from the nitrogen atom-contained gas may be the oxygen gas.

The material gases that may be used for the purpose of the present invention may preferably be any one or more of silane gases as expressed in terms of the chemical formula of SiₙH₂ₙ₊₂ (n is an integer). Those material gases may be diluted by using any suitable diluting gas.

In order to permit more oxygen radicals to be generated and supplied into the film forming space, the gas that causes the plasma to be discharged for generating the desired active species within the plasma generating space should preferably contain the oxygen gas.

The advantage of the thin film formation method according to the present invention is that it allows for the formation of thin films having the good interfacial property between the silicon substrate and silicon oxide film at the low temperature and having the low interfacial trap density.

### BEST MODE OF EMBODYING THE INVENTION

Now, several preferred embodiments of the present invention will be described by referring to the accompanying drawings.

FIG. 1 is a schematic diagram illustrating one example of the thin film formation apparatus that may be used in conjunction with the first embodiment of the thin film formation method of the present invention. In this apparatus, silane gases may preferably be used as the material gas, and the silicon oxide film may be formed as the gate insulating film on the silicon substrate.

The apparatus includes a vacuum vessel 1 that comprises a vessel 2, any suitable insulating material 4 and a high frequency electrode 3. The vacuum vessel 1 may be maintained under the desired vacuum state by means of an appropriate evacuating device 5. The vacuum vessel 1 contains a conductive partition plate 101 made of any suitable conductive material, and is internally separated into two compartments by the conductive partition plate 101, one being an upper compartment and the other being a lower compartment. The upper compartment serves as the plasma generating space 8, and the lower compartment serves as the film forming space 9.

The high frequency electrode 3, which is provided in the plasma generating space 8, is connected to a high frequency power supply 11.

A substrate holding mechanism 6 is provided in the film forming space 9, and a silicon substrate 10 being processed may be placed on the substrate holding mechanism 6 so that it can face opposite the conductive partition plate 101. The substrate holding mechanism 6 contains a heater 7 therein for heating the silicon substrate 10 to the predetermined constant temperature.

The conductive partition plate 101 that is provided for separating the vacuum vessel 1 into the two compartments is wholly formed like a flat shape having the desired thickness. The conductive partition plate 101 has a plurality of penetrating holes 41 distributed at regular intervals, and the plasma generating space 8 and film forming space 9 may only communicate with each other through those penetrating holes 41. In the conductive partition plate 101, furthermore, a first inner space 31 and a second inner space 21 are formed so that they are separated from each other.

The first inner space 31 is connected to a material gas supply source 52 by way of a flow rate regulator 63. The material gases may be any one or more of silane gases as expressed in terms of the chemical formula of SiₙH₂ₙ₊₂ (n is any integer).

The second inner space 21 is connected to an oxygen gas supply source 51 by way of flow rate regulators 68, 64, and is also connected to NₓO_{y} gas supply source 66 by way of flow rate regulators 67, 64, from which the nitrogen atom-contained gas (NₓO_{y} gas, x, y being integers) are supplied. The gases that may be supplied from the NₓO_{y} gas supply source 55 into the second inner space 21 may be any one or more of dinitrogen monoxide (N₂O), nitrogen monoxide (NO) and nitrogen dioxide (NO₂).

In each of the first inner space 31 and second inner space 21, a plurality of material gas diffusion holes 32 and a plurality of gas diffusion holes 22 are provided, respectively, and each of the first inner space 31 and second inner space 21 is connected to the corresponding film forming space 9 through the respective material gas diffusion holes 32 and gas diffusion holes 22.

Next, the thin film formation method that may be used in conjunction with the thin film forming apparatus having the construction described above will be described below. A silicon substrate 10 being processed may be transported into the vacuum vessel 10 by means of any suitable transfer robot (not shown), and may then be placed onto the substrate holding mechanism 6 in the film forming space 9.

The substrate holding mechanism 6 may previously be heated to the predetermined constant temperature, and the silicon substrate 10 may then be maintained at the constant temperature through the substrate holding mechanism 6.

The vacuum vessel 1 may be evacuated by any suitable evacuator, placing the vacuum vessel under the reduced pressure or vacuum state.

The oxygen gas may be introduced from the oxygen gas supply source 51 into the plasma generating space 8 at the flow rate regulated by the flow rate regulator 61, and separately and independently from this, the oxygen gas may be introduced from the oxygen gas supply source 51 into the second inner space 21 at the flow rate regulated by the flow rate regulators 64, 68.

While the oxygen gases are introduced into the plasma generating space 8 and second inner space 21, the material gas, for example, one or more of silane gases as expressed in terms of the chemical formula of SᵢH₂ₙ₊₂ (n is any integer) may be introduced from the material gas supply source 52 into the first inner space 31 at the flow rate regulated by the flow rate regulator 63. The silane gases, which have been introduced into the first inner space 31, may then be supplied into the film forming space 9 through the material gas diffusion holes 32.

Under the above conditions, electric power may be supplied to the high frequency electrode 3 from the high frequency power supply 11, thereby generating oxygen plasma within the plasma generating space 8. The oxygen plasma thus generated may cause neutral excited species, or radical (active species), to be generated.

The oxygen radicals thus generated within the plasma generating space 8 has a long life, and may be supplied into the film forming space 9 through the plurality of penetrating holes 41 on the conductive partition plate 101, together with the non-excited oxygen. Within the plasma generating space 8, the charged particles may also be generated, but have a short life. Thus, those particles will disappear while passing through the penetrating holes 41

In the meantime, with its flow rate being regulated by the flow rate regulators 64, 67, the NₓO_{y} gas may continue to be supplied into the second inner space 21 from the NₓO_{y} gas supply source 55, during the predetermined period from the time of start of formation of the silicon oxide film on the silicon substrate until the time of end of that formation, while NO gas that has been introduced into the second inner space 21 may be supplied into the film forming space 9 through the gas diffusion holes 22.

Within the film forming space 9, the oxygen radicals that have been supplied into the film forming space 9 may then be caused to react with the silane gases that have been supplied into the film forming space 9 from the second inner space 31 and through the material gas diffusion holes 32. During the sequence of reactions thus triggered, the NₓO_{y} gas introduced into the second inner space 21 may be introduced into the film forming space 9 through the gas diffusion holes 22, and may be mixed into the interface between the silicon substrate 10 and silicon oxide film, providing the silicon oxide film having the improved interfacial property.

The oxygen gas may also be introduced from the oxygen gas supply source 51 into the second inner space 21 at the flow rate regulated by the flow rate regulators 64, 68. The oxygen gas may be introduced into the second inner space 21 at the time when the formation of the silicon oxide film on the silicon substrate is started or after the introduction of the NₓO_{y} gas is stopped.

The mixture gases composed of the NO gas and oxygen gas introduced into the second inner space 21 or the oxygen gas may be supplied into the film forming space 9 through the gas diffusion holes 22. By supplying the oxygen gas from the second inner space 21 into the film forming space 9 through the gas diffusion holes 22, it is possible to control the respective quantities of the oxygen radicals to be supplied to the film forming space 9 independently of each other. Even if the quantity of oxygen radicals is increased by controlling the discharging power required for forming the high quality thin film, the sufficient quantity of oxygen can be supplied. In this way, the loss of the oxygen that may have been caused by the chemical reaction during the conventional thin film forming process can be compensated for sufficiently, and the thin film having the higher quality than the conventional one can be provided.

### Example 1

The silicon oxide film was formed on the silicon substrate by the chemical vapor deposition (CVD) under the following process conditions, using the thin film formation apparatus shown in FIG. 1.

(1) Substrate: silicon substrate
(2) Oxygen gas to be introduced into the plasma generating space:

Flow rate of 5.0×10⁻¹ (1/mm) (1500 sccm)

(3) High frequency power: 150 W
(4) Material gas SiₙH₂ₙ₊₂ (n=1)

Flow rate of 4.0×10⁻³ (1/mm) (20 sccm)

(5) NₓO_{y} gas (x=1, y=2) to be introduced into the second inner space:

Flow rate of 4.0×10⁻⁴ (1/mm) (2 sccm)

(6) Oxygen gas to be introduced into the second inner space:

Flow rate of 4.0×10⁻⁴ (1/mm) (2 sccm)

(7) Temperature of substrate (film forming temperature): 300° C.
(8) Pressure in the plasma generating space: 40 Pa
(9) Pressure in the film forming space: 40 Pa
(10) Thickness of whole thin film (film forming time): 100 nm (4 min)

The introduction of the NₓO_{y} gas took place for about 24 seconds after the film forming process was started, and then the flow rate was set to zero (0), while the oxygen gas was introduced together with the NₓO_{y} gas after the film forming process was started. Even after the flow rate of the NₓO_{y} gas was set to zero (0), the oxygen gas was still introduced into the second inner space and the film forming process was continued.

By following the process described above, the interfacial trap density of 10¹¹/cm² eV can be achieved by mixing 10% of nitrogen with regard to the silane gas into the region located less than 10 nm deep from the interface between the silicon substrate and silicon oxide film.

Two experiments were conducted under the same conditions as for the example 1 described above. In the first experiment, the quantity of NₓO_{y} gas being introduced into the second inner space was continually decreased for about 24 seconds from the beginning of the film formation as shown in FIG. 2 (b), and in the second experiment, the quantity of NₓO_{y} gas was gradually decreased as shown in FIG. 2 (c). The interfacial trap density that was achieved in those experiments was equivalent to the interfacial trap density achieved when the quantity of NₓO_{y} gas being introduced into the second inner space remained constant as shown in FIG. 2 (a).

### BRIEF DESCRIPTION OF DRAWINGS

FIG. 1 is a schematic diagram that represents the longitudinal cross-section of one example of the thin film formation apparatus that implements the first embodiment of the thin film formation method of the present invention; and

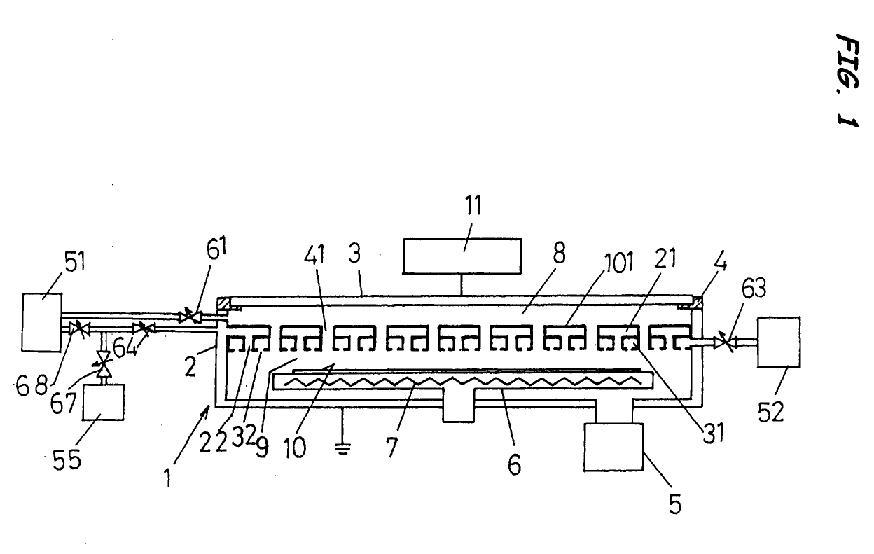

FIGS. 2 (a), (b) and (c) represent a graph of the relationship of the film forming time versus the amount of NₓO_{y} gas added, respectively.

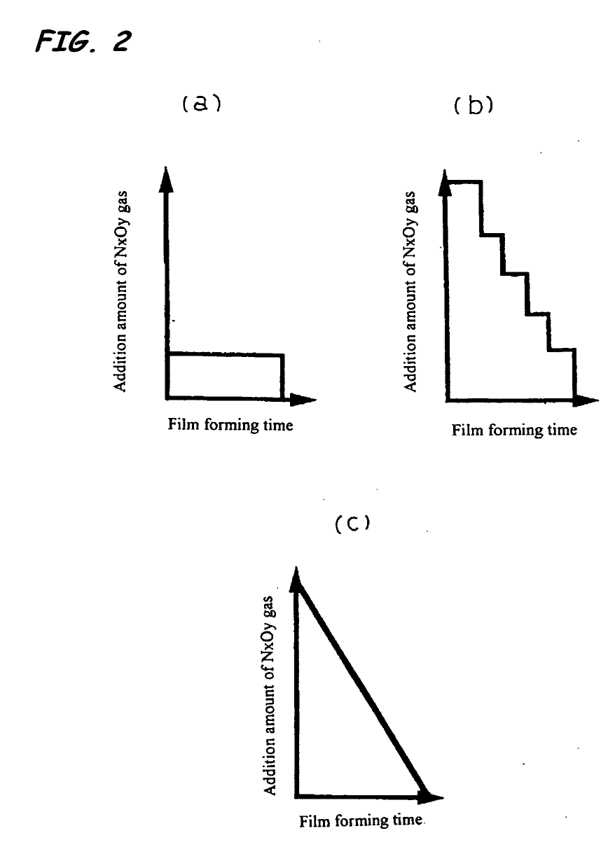

1. In the thin film formation apparatus that includes a vacuum vessel internally separated into two compartments by means of a conductive partition plate, one of the two compartments serving as a plasma generating space in which a high frequency electrode is disposed and the other serving as a film forming space in which a substrate holding mechanism is disposed for holding a silicon substrate firmly thereon, the conductive partition plate having a plurality of penetrating holes through which the plasma generating space and film forming space communicate with each other, and further including a first inner space separated from the plasma generating space and communicating with the film forming space through a plurality of material gas diffusion holes provided on the conductive partition plate and a second inner space separated from the first inner space and communicating with the film forming space through a plurality of gas diffusion holes provided on the conductive partition plate, a thin film formation method for forming a thin film on a silicon substrate, including introducing a gas into the plasma generating space for discharging plasma and generating a desired active species (radical) by the discharged plasma, introducing the desired active species generated in the plasma generating space into the film forming space through the plurality of penetrating holes on the conductive partition plate, introducing the material gas supplied from its external source into the first inner space through the plurality of material gas diffusion holes, and introducing any suitable gas other than the material gas supplied from the external source into the film forming space through the plurality of gas diffusion holes, thereby forming a silicon oxide film on the silicon substrate by allowing the active species and material gas introduced into the film forming space to react with each other, wherein any suitable gas other than the material gas introduced into the second inner space is a nitrogen atom-contained gas, and wherein said method further includes:
adjusting the flow rate of the nitrogen atom-contained gas being introduced into the second inner space during the formation of the silicon oxide film on the silicon substrate to at least the maximum value, at least, at the time of start of the formation of the silicon oxide film on the silicon substrate.

2. The method as defined in claim 1, wherein the flow rate of the nitrogen atom-contained gas to be introduced into the second inner space is set equal to a constant flow rate during a predetermined period from the start time of the formation of the silicon oxide film on the silicon substrate until the end time of the same.

3. The method as defined in claim 1, wherein the flow rate of the nitrogen atom-contained gas to be introduced into the second inner space is continually decreased with the elapse of the time, beginning with the start time of the formation of the silicon oxide film on the silicon substrate.

4. The method as defined in claim 1, wherein the flow rate of the nitrogen atom-contained gas introduced into the second inner space is gradually decreased with the elapse of the time, beginning with the start time of the formation of the silicon oxide film on the silicon substrate.

5. The method as defined in claim 1, wherein the nitrogen atom-contained gas as any suitable gas other than the material gas to be introduced into the second inner space is combined with the oxygen atom-contained gas as the suitable gas that is different from the nitrogen atom-contained gas.

6. The method as defined in claim 5, wherein the flow rate of the nitrogen atom-contained gas to be introduced into the second inner space is set equal to zero (0) at a predetermined time during the period from the start time of the formation of silicon oxide film until the end time of the same, and the oxygen atom-contained gas as the suitable gas that is different from the nitrogen atom-contained gas continues to be introduced into the second inner space even after the flow rate has been set equal to zero (0).

7. The method as defined in claim 1, wherein the material gas is any one or more of silane gases as expressed in terms of the chemical formula of SᵢH₂ₙ₊ₙ (n denotes any integer).

8. The method as defined in claim 1, wherein the nitrogen atom-contained gas is any one or more of dinitrogen monoxide (N₂O), nitrogen monoxide (NO) and nitrogen dioxide (NO₂).
